(19) United States
(12) Patent Application Publication
(10) Pub. No.: US 2008/0145783 A1
(43) Pub. Date: Jun. 19, 2008

(54) Photosensitive Resin Composition and Organic Insulating Film Produced Using the Same

(75) Inventors: Sang Won CHO, Seoul (KR); Min Sung KIM, Gunpo-si (KR); Dong Ju SHIN, Suwon-si (KR); Kil Sung LEE, Gwacheon-si (KR)

Correspondence Address: SUMMA, ALLAN & ADDITON, P.A., 11610 NORTH COMMUNITY HOUSE ROAD, SUITE 200, CHARLOTTE, NC, 28277, US

(73) Assignee: CHEIL INDUSTRIES INC., Gumi-si (KR)

(21) Appl. No.: 11/951,671

(22) Filed: Dec. 6, 2007

(30) Foreign Application Priority Data
Dec. 19, 2006 (KR) 10-2006-0130489

(51) Int. Cl. G03F 7/004

(52) U.S. Cl. 430/280.1; 430/286.1

(57) ABSTRACT

A photosensitive resin composition is provided. The composition includes an acrylic copolymer, a photoacid generator and a solvent. The acrylic copolymer includes structural units of Formulae 1, 2, 3 and 4, which are described in the specification. The composition exhibits excellent performance characteristics in terms of mechanical and thermal properties, transmittance, insulating properties, transparency, developability, residual film ratio, heat resistance, flatness and the like. Particularly, the use of the composition facilitates the formation of a pattern as an interlayer insulating film. The composition can also be used to produce a thick film with high transmittance. Therefore, the composition is effectively used as a material for an interlayer insulating layer in LCD fabrication processes. An organic insulating film produced using the composition is also provided.

### CROSS-REFERENCE TO RELATED APPLICATION

This non-provisional application claims priority under 35 USC Section 119 from Korean Patent Application No. 10-2006-0130489, filed on Dec. 19, 2006, which is hereby incorporated by reference in its entirety.

### FIELD OF THE INVENTION

The present invention relates to a photosensitive resin composition and an organic insulating film produced using the photosensitive resin composition.

### BACKGROUND OF THE INVENTION

Recent increased demand for liquid crystal display (LCD) panels for televisions and monitors has increased the need for large-size glasses and high-definition panels. This has increased the need for photoresists suitable for processing large-size glasses.

Photo processes conducted on the large-size glasses are important in determining production output. In the photo processes, the quality of microcircuits formed in subsequent steps is directly influenced by characteristics of photoresist films, e.g., application characteristics, transparency (free of optical defects), development contrast, resolution, adhesiveness to substrates, film retentiveness and sensitivity. In particular, the sensitivity of photoresists formed during photo processes is an important factor affecting the tact time of mass production lines. Therefore, the use of photoresists with high sensitivity can improve productivity.

At present, positive-type systems composed of 2,1,5-diazonaphthoquinone (hereinafter, referred to as ‘DNQ’) using i-line and an acrylic resin are most widely used as materials for resists for LCDs. The systems undergo a photoreaction when irradiated with light. The photoreaction of the systems occurs via DNQ, which is insoluble in an alkaline solution before exposure to light and becomes alkali-soluble upon the light exposure. When the alkali-soluble DNQ is developed with an aqueous alkaline developer, the exposed regions are dissolved away.

The inherently alkali-soluble acrylic resin is cross-linked with the DNQ to make the acrylic resin insoluble in an alkaline solution. Accordingly, regions of the systems exposed to light dissolve due to the decomposition of DNQ, while in regions of the system not exposed to light, the acrylic resin is cross-linked with the DNQ and is not dissolved. As a result, the shape of a mask appears during a development process.

The DNQ functions to impede the dissolution of the highly alkali-soluble acrylic resin, and is thus called a “dissolution inhibitor.” Such systems are known to have a light sensitivity of from about 300 to about 400 mJ/cm². High sensitivity of the systems is required for increased throughput and improved reactivity in LCD fabrication processes.

Chemically amplified photoresists comprised of a photoacid generator (PAG) and a polymer combined with a dissolution inhibitor have been developed to increase the sensitivity of the system. When the chemically amplified photoresists are exposed to light, the dissolution inhibitor bonded to the skeleton of the polymer is hydrolyzed by the catalytic action of an acid generated from the photoacid generator, causing a change in the polarity of the polymer. The polymer with the changed polarity is developed with a polar or non-polar solvent to form a positive- or negative-type photosensitive film pattern. U.S. Pat. No. 4,491,628 discloses polyvinylphenol protected with a t-butoxycarbonyl group as an example of a resin useful in a chemically amplified photoresist.

Interlayer insulating films are used to insulate layers in thin film transistor (TFT)-type liquid crystal display devices and integrated circuit devices. Photosensitive materials that can be simply processed and can have superior flatness are required for the production of interlayer insulating films with desired shaped patterns. The structure of TFT-type liquid crystal display devices varies along with an increase in the definition of liquid crystal displays (LCDs). For example, some interlayer insulating films with poor insulating properties must be thick to provide a high degree of flatness. However, the transparency of the thick interlayer insulating films is inevitably lowered.

### SUMMARY OF THE INVENTION

The present invention provides a photosensitive resin composition with excellent mechanical and thermal properties, high improved transmittance, superior insulating properties and improved physical properties. The present invention further provides an organic insulating film produced using the photosensitive resin composition.

In accordance with one aspect of the present invention, there is provided a photosensitive resin composition comprising a binder resin, a photoacid generator and a solvent wherein the binder resin is an acrylic copolymer having structural units represented by Formulae 1, 2, 3 and 4:

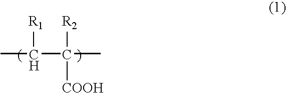

wherein R₁ and R₂ are each independently hydrogen or a methyl group;

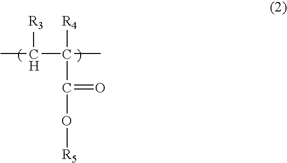

wherein R₃ and R₄ are each independently hydrogen or a methyl group, and R₅ is hydrogen, fluorine, hydroxyl, or a C₁-C₃₀ linear or cyclic alkyl, hydroxyalkyl, alkoxy, epoxy, alkoxyalkyl, ester or polycyclic group which is dissociated or not dissociated by an acid;

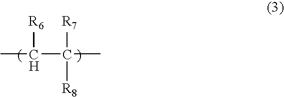

wherein R₆ and R₇ are each independently hydrogen or a methyl group, and R₈ is hydrogen, fluorine, hydroxyl, or a C₁-C₃₀ linear or cyclic alkyl, hydroxyalkyl, alkoxy, epoxy, alkoxyalkyl, ester or polycyclic group which is dissociated or not dissociated by an acid; and

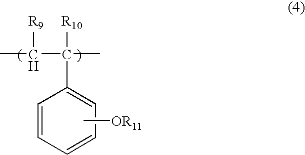

wherein R₉ and R₁₀ are each independently hydrogen or a methyl group, and R₁₁ is a methyl, ethyl, isopropyl, t-butyl, t-amyl, isobornyl, tetrahydropyranyl, naphthalenyl, isomenthyl, tricyclodecanyl, norbomyl, tetracyclododecyl, decalinyl, cyclohexyl, adamantyl, methyladamantyl, ethyladamantyl or alkoxyalkyl group.

The copolymer can have a molecular weight (M_{w}) of about 1,000 to about 200,000.

The copolymer can be present in an amount of about 10 to about 30 parts by weight, based on 100 parts by weight of the solvent.

The photoacid generator can be an onium salt compound containing a C₁-C₁₀ fluoroalkylsulfonate ion as an anion.

The photoacid generator can be present in an amount of about 0.01 to about 15 parts by weight, based on 100 parts by weight of the acrylic copolymer.

The composition of the present invention further comprises a resin, a surfactant, an adhesion promoter and/or an attachment improver.

In accordance with another aspect of the present invention, there is provided an organic insulating film produced using the photosensitive resin composition.

### DETAILED DESCRIPTION OF THE INVENTION

The present invention now will be described more fully hereinafter in the following detailed description of the invention, in which some, but not all embodiments of the invention are described. Indeed, this invention may be embodied in many different forms and should not be construed as limited to the embodiments set forth herein; rather, these embodiments are provided so that this disclosure will satisfy applicable legal requirements.

The present invention provides a photosensitive resin composition comprising a binder resin, a photoacid generator and a solvent.

The binder resin can be an acrylic copolymer having structural units represented by Formulae 1, 2, 3 and 4:

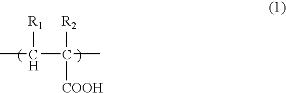

wherein R₁ and R₂ are each independently hydrogen or a methyl group;

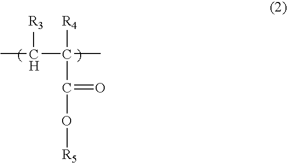

wherein R₃ and R₄ are each independently hydrogen or a methyl group, and R₅ is hydrogen, fluorine, hydroxyl, or a C₁-C₃₀ linear or cyclic alkyl, hydroxyalkyl, alkoxy, epoxy, alkoxyalkyl, ester or polycyclic group which is dissociated or not dissociated by an acid;

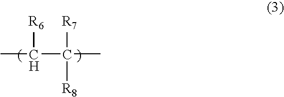

wherein R₆ and R₇ are each independently hydrogen or a methyl group, and R₈ is hydrogen, fluorine, hydroxyl, or a C₁-C₃₀ linear or cyclic alkyl, hydroxyalkyl, alkoxy, epoxy, alkoxyalkyl, ester or polycyclic group which is dissociated or not dissociated by an acid; and

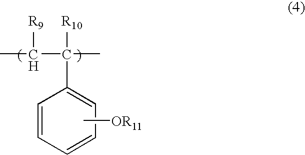

wherein R₉ and R₁₀ are each independently hydrogen or a methyl group, and R₁₁ is a methyl, ethyl, isopropyl, t-butyl, t-amyl, isobornyl, tetrahydropyranyl, naphthalenyl, isomenthyl, tricyclodecanyl, norbomyl, tetracyclododecyl, decalinyl, cyclohexyl, adamantyl, methyladamantyl, ethyladamantyl or alkoxyalkyl group.

The acrylic copolymer used in the present invention exhibits excellent mechanical and thermal properties, high transparency, and low dielectric constant. The epoxy group of the copolymer allows increased mechanical strength. The present acrylic copolymer is suitable for a positive-type resist which can be developed by an alkaline developer in the presence of a small amount of an acid generator.

The copolymer has a molecular weight (M_{w}) of about 1,000 to about 200,000, for example about 3,000 to about 50,000. A copolymer having a molecular weight less than about 1,000 may be too soft to form a photoresist thin film. Meanwhile, a photoresist thin film formed using a copolymer having a molecular weight more than about 200,000 tends to be brittle, possibly causing the formation of an unstable pattern.

The acrylic copolymer can have a structure represented by Formula 5:

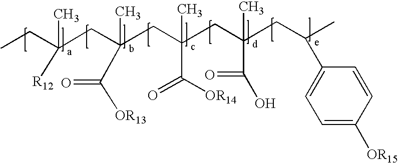

wherein R₁₂ is H, F, hydroxyl, or a C₁-C₃₀ linear or cyclic alkyl, hydroxyalkyl, alkoxy, epoxy, alkoxyalkyl, ester or polycyclic group which is dissociated or not dissociated by an acid or aryl or phenyl; R₁₃ and R₁₄ are each independently H, F, hydroxyl, or a C₁-C₃₀ linear or cyclic alkyl, hydroxyalkyl, alkoxy, epoxy, alkoxyalkyl, ester or polycyclic group which is dissociated or not dissociated by an acid; R₁₅ is a methyl, ethyl, isopropyl, t-butyl, t-amyl, isobomyl, tetrahydropyranyl, naphthalenyl, isomenthyl, tricyclodecanyl, norbornyl, tetracyclododecyl, decalinyl, cyclohexyl, adamantyl, methyladamantyl, ethyladamantyl or alkoxyalkyl group; and a, b, c, d and e each represent the molar ratios of the respective structural units, are each greater than 0 and less than 1, and the sum of a, b, c, d and e is 1.

As used herein, the terms hydroxyalkyl, alkoxy, and alkoxyalkyl can include C₁-C₂₀ hydroxyalkyl, C₁-C₂₀ alkoxy, and C₁-C₂₀ alkoxyalkyl groups, the terms epoxy and ester can include C₂-C₂₀ epoxy and C₂-C₂₀ ester groups, the term polycyclic group can include C₅-C₂₀ polycyclic groups, and the term aryl can include to C₆-C₂₀ aryl groups.

The content of the binder resin in the photosensitive resin composition of the present invention may vary depending on various factors, such as the type of solvent and acid generator used and lithography conditions employed. Exemplary embodiments of the invention include about 10 to about 30 parts by weight of the binder resin dissolved in 100 parts by weight of the solvent.

The use of the binder resin in an amount of less than about 10 parts by weight may cause only a small difference in solubility between exposed and unexposed regions, making the formation of a pattern difficult. Meanwhile, the use of the binder resin in an amount of more than about 30 parts by weight may lead to an increased solubility in an aqueous alkaline solution, and as a result, a pattern tends to be difficult to form.

The photoacid generator used in the present invention is a compound that is dissociated by light to generate an acid. Any known photoacid generator that has been used in the art can be used without any particular limitation.

An exemplary photoacid generator useful in the composition of the present invention, which can be described as a chemically amplified photoresist composition, can include an onium salt compound containing a C₁-C₁₀ fluoroalkylsulfonate ion as an anion. Examples of suitable onium salt compounds include iodonium salts, sulfonium salts, phosphonium salts, diazonium salts, and pyridinium salts. Specific examples of such onium salt compounds include without limitation di-t-butylphenyliodonium-9, 10-diethoxyanthracene-2-sulfonate, diphenyliodonium trifluoromethane sulfonate, diphenyliodonium nonafluoromethane sulfonate, di-(4-t-butylbenzene)iodonium trifluoromethane sulfonate, triphenylsulfonium trifluoromethane sulfonate, triphenylsulfonium nonafluoromethane sulfonate, diphenyl-4-methylphenylsulfonium trifluoromethane sulfonate, triphenylsulfonium p-toluene sulfonate, triphenylsulfonium 10-camphor sulfonate, dimethyl(4-naphthol)sulfonium trifluoromethane sulfonate, dimethyl(4-naphthol)sulfonium p-toluene sulfonate, dimethyl(4,7-dihydroxynaphthalene)sulfonium trifluoromethane sulfonate, dimethyl(4,7-dihydroxynaphthalene)sulfonium 10-camphor sulfonate, dimethyl(4,7-dihydroxynaphthalene)sulfonium p-toluene sulfonate, dimethyl(4,7-dihydroxynaphthalene)sulfonium nonafluoromethane sulfonate, and dimethyl(4,7-dihydroxynaphthalene)sulfonium 3-pyridine sulfonate. These onium salt compounds may be used alone or as a mixture of two or more thereof.

The content of the photoacid generator can be between 0.01 and 15 parts by weight, based on 100 parts by weight of the binder resin. The use of the photoacid compound in an amount of less than about 0.01 parts by weight may cause only a small difference in solubility between exposed and unexposed regions, making formation of a pattern difficult. Meanwhile, excess photoacid compound of more than about 15 parts by weight may remain unreacted upon light irradiation for a short time and may lower the solubility of the composition in an aqueous alkaline solution to make the development of the composition difficult.

Any typical organic solvent can be used to prepare the photoresist composition of the present invention. Examples of organic solvents include, but are not limited to, ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol methyl ether acetate, propylene glycol propyl ether acetate, diethylene glycol dimethyl ether, ethyl lactate, toluene, xylene, methyl ethyl ketone, cyclohexanone, 2-heptanone, 3-heptanone, 4-heptanone, and the like, and mixtures thereof.

In addition to these organic solvents, if desired, N-methylformamide, N,N-dimethylformamide, N-methylacetamide, N,N-dimethylacetamide, N-methylpyrrolidone, dimethylsulfoxide, triphenylimidazole, alcohol or a mixture thereof may be used as an auxiliary solvent.

So long as the objects of the present invention are not impaired, any additive compatible with the photosensitive resin composition of the present invention may be further added, if necessary. For example, at least one additive selected from resins, surfactants, adhesion promoters and attachment improvers can be used to improve the performance of resist films.

The photosensitive resin composition of the present invention can be prepared by dissolving the binder resin and the photoacid generator (PAG) in the organic solvent and filtering the solution through a microfilter, in accordance with known preparation methods of general photosensitive resin compositions.

The photosensitive resin composition thus prepared is applied to a substrate by a known coating technique, such as spraying, roll coating or spin coating, to form a photoresist thin film, and is patterned in a subsequent step to form a photoresist pattern. Hereinafter, an exemplary method for the formation of a resist pattern in a fabrication of LCD will be illustrated.

An explanation of the formation of a film using a chemically amplified photosensitive resin composition will be given below. First, the photosensitive resin composition of the present invention is applied on top of a glass or silicon wafer substrate and pre-baked on a hot plate at 80-150° C. for 1-15 minutes to form a photoresist film. After a mask is placed on the photoresist film, UV light is irradiated, followed by post-exposure baking (PEB) on a hot plate at 80-150° C. for 1-15 min. Subsequently, the resulting structure is developed with a developer, e.g., an aqueous tetramethylammonium hydroxide (TMAH, 0.1-5 wt %) solution, by a previously known technique, e.g., dipping, puddling or spraying, for 30-180 seconds to form a photoresist pattern. The photoresist pattern is cleaned with distilled water for 30-90 seconds to remove unnecessary portions therefrom, and dried to form a pattern. The pattern is cured in a heater, e.g., an oven, at 150-250° C. for 30-90 minutes to form the final pattern.

Hereinafter, the present invention will be explained in more detail with reference to the following examples. However, these examples are given for the purpose of illustration only and are not intended to limit the present invention.

### EXAMPLES

### Synthesis Example 1

20g of methacrylic acid, 10 g of styrene, 30 g of tert-butoxycarbonylstyrene, 30 g of glycidyl methacrylate and 10 g of 2-methyladamantanyl methacrylate are put into a polymerization flask equipped with a condenser and a stirrer. 10 g of 2,2′-azobisisobutyronitrile as a polymerization initiator is added to the polymerization flask, and then 200 g of purified tetrahydrofuran is added thereto to dissolve the mixture. The solution is polymerized under a nitrogen atmosphere at 65° C. for 24 hours. After completion of the polymerization, the polymerization product is precipitated in petroleum ether/ethyl ether, passed through a glass filter, and dried in vacuo at room temperature for 24 hours to afford the polymer of Formula 6 having a weight-average molecular weight of 10,500.

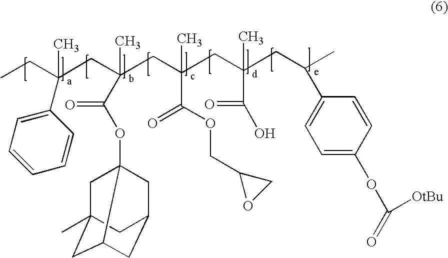

wherein each a, b, c, d and e is greater than 0 and lower than 1 and the sum of a, b, c, d and e is 1.

### Synthesis Example 2

20 g of methacrylic acid, 10 g of styrene, 30 g of tert-butoxycarbonylstyrene, 30 g of 2-hydroxyethyl methacrylate and 10 g of 2-methyladamantanyl methacrylate are put into a polymerization flask equipped with a condenser and a stirrer. 10 g of 2,2′-azobisisobutyronitrile as a polymerization initiator is added to the polymerization flask, and then 200 g of purified tetrahydrofuran is added thereto to dissolve the mixture. The solution is polymerized under a nitrogen atmosphere at 65° C. for 24 hours. After completion of the polymerization, the polymerization product is precipitated in petroleum ether/ethyl ether, passed through a glass filter, and dried in vacuo at room temperature for 24 hours to afford the polymer of Formula 7 having a weight-average molecular weight of 14,600.

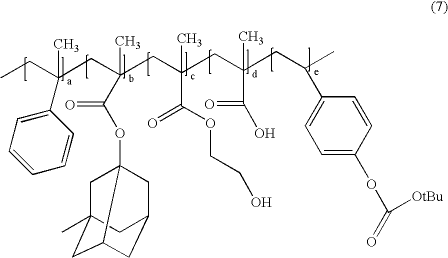

wherein each a, b, c, d and e is greater than 0 and lower than 1 and the sum of a, b, c, d and e is 1.

### Synthesis Example 3

20 g of methacrylic acid, 10 g of styrene, 30 g of tert-butoxystyrene, 30 g of glycidyl methacrylate and 10 g of 2-methyladamantanyl methacrylate are put into a polymerization flask equipped with a condenser and a stirrer. 10 g of 2,2′-azobisisobutyronitrile as a polymerization initiator is added to the polymerization flask, and then 200 g of purified tetrahydrofuran is added thereto to dissolve the mixture. The solution is polymerized under a nitrogen atmosphere at 65° C. for 24 hours. After completion of the polymerization, the polymerization product is precipitated in petroleum ether/ethyl ether, passed through a glass filter, and dried in vacuo at room temperature for 24 hours to afford the polymer of Formula 8 having a weight-average molecular weight of 9,600.

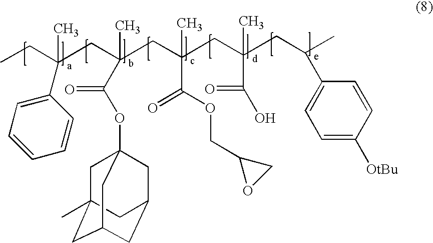

wherein each a, b, c, d and e is greater than 0 and lower than 1 and the sum of a, b, c, d and e is 1.

### Synthesis Example 4

20 g of methacrylic acid, 10 g of styrene, 30 g of tert-butoxystyrene, 30 g of 2-hydroxymethacrylate and 10 g of 2-methyladamantanyl methacrylate are put into a polymerization flask equipped with a condenser and a stirrer. 10 g of 2,2′-azobisisobutyronitrile as a polymerization initiator is added to the polymerization flask, and then 200 g of purified tetrahydrofuran is added thereto to dissolve the mixture. The solution is polymerized under a nitrogen atmosphere at 65° C. for 24 hours. After completion of the polymerization, the polymerization product is precipitated in petroleum ether/ethyl ether, passed through a glass filter, and dried in vacuo at room temperature for 24 hours to afford the polymer of Formula 9 having a weight-average molecular weight of 10,500.

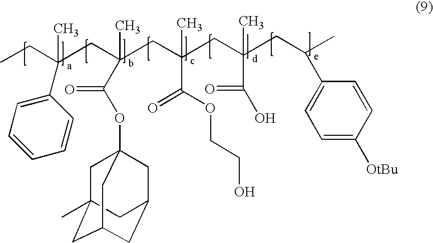

wherein each a, b, c, d and e is greater than 0 and lower than 1 and the sum of a, b, c, d and e is 1.

### Synthesis Example 5

20 g of methacrylic acid, 10 g of styrene, 30 g of tert-butylstyrene, 30 g of glycidyl methacrylate and 10 g of 2-methyladamantanyl methacrylate are put into a polymerization flask equipped with a condenser and a stirrer. 10 g of 2,2′-azobisisobutyronitrile as a polymerization initiator is added to the polymerization flask, and then 200 g of purified tetrahydrofuran is added thereto to dissolve the mixture. The solution is polymerized under a nitrogen atmosphere at 65° C. for 24 hours. After completion of the polymerization, the polymerization product is precipitated in petroleum ether/ethyl ether, passed through a glass filter, and dried in vacuo at room temperature for 24 hours to afford the polymer of Formula 10 having a weight-average molecular weight of 10,500.

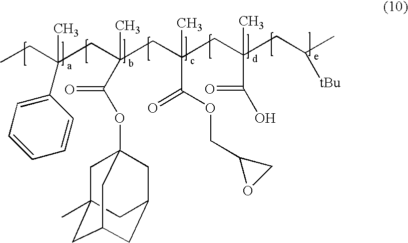

wherein each a, b, c, d and e is greater than 0 and lower than 1 and the sum of a, b, c, d and e is 1.

### Synthesis Example 6

20 g of methacrylic acid, 10 g of styrene, 30 g of tert-butyl acrylate, 30 g of 2-hydroxymethacrylate and 10 g of 2-methyladamantanyl methacrylate are put into a polymerization flask equipped with a condenser and a stirrer. 10 g of 2,2′-azobisisobutyronitrile as a polymerization initiator is added to the polymerization flask, and then 200 g of purified tetrahydrofuran is added thereto to dissolve the mixture. The solution is polymerized under a nitrogen atmosphere at 65° C. for 24 hours. After completion of the polymerization, the polymerization product is precipitated in petroleum ether/ethyl ether, passed through a glass filter, and dried in vacuo at room temperature for 24 hours to afford the polymer of Formula 11 having a weight-average molecular weight of 10,500.

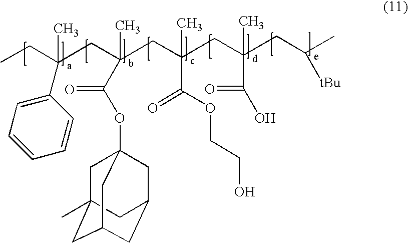

wherein each a, b, c, d and e is greater than 0 and lower than 1 and the sum of a, b, c, d and e is 1.

### Example 1

1.0 g of the acrylic polymer protected with a t-butoxycarbonyl group and substituted with an epoxy group, which is prepared in Synthesis Example 1, and 0.03 g of triphenylsulfonium triflate as a photoacid generator are dissolved in 3.0 g of propylene glycol monomethyl ether acetate. The solution is filtered through a 0.2 μm syringe filter to prepare a photosensitive resin composition in the form of a solution.

### Example 2

A photosensitive resin composition in the form of a solution is prepared in the same manner as in Example 1, except that the acrylic polymer prepared in Synthesis Example 2 is used instead of that prepared in Synthesis Example 1.

### Example 3

A photosensitive resin composition in the form of a solution is prepared in the same manner as in Example 1, except that the acrylic polymer prepared in Synthesis Example 3 is used instead of that prepared in Synthesis Example 1.

### Example 4

A photosensitive resin composition in the form of a solution is prepared in the same manner as in Example 1, except that the acrylic polymer prepared in Synthesis Example 4 is used instead of that prepared in Synthesis Example 1.

### Comparative Example 1

A photosensitive resin composition in the form of a solution is prepared in the same manner as in Example 1, except that the acrylic polymer prepared in Synthesis Example 5 is used instead of that prepared in Synthesis Example 1.

### Comparative Example 2

A photosensitive resin composition in the form of a solution is prepared in the same manner as in Example 1, except that the acrylic polymer prepared in Synthesis Example 6 is used instead of that prepared in Synthesis Example 1.

Patterned films are produced using the photosensitive resin compositions prepared in Examples 1 to 4 and Comparative Examples 1 and 2 in accordance with the following procedure.

Each of the compositions in the form of a solution is spin-coated at 2,000 rpm on a glass substrate, pre-baked at 120° C. for 90 seconds, irradiated with light at an exposure dose of 300-600 mJ/cm² through a patterned mask, and subjected to post-exposure baking (PEB) at 120° C. for 90 seconds to form a pattern. The pattern is developed with an aqueous tetramethylammonium hydroxide (TMAH, 2.38 wt %) solution as a developer for 40-70 seconds, washed with distilled water, and cured in an oven at 200° C. for 60 minutes to produce a patterned film having a 0.5 micron (μm) line/space pattern.

The physical properties of each of the patterns are evaluated by the following respective methods. The obtained results are shown in Table 1.

1) Sensitivity is determined at a minimum exposure dose at which the pattern was formed.

2) Resolution is defined as a minimum line size in the patterned film.

3) Residual film ratio is evaluated on a thickness variation of the film before and after the development.

4) Transparency is evaluated by measuring the transmittance at 400 nm of the patterned film using a spectrophotometer.

5) Resistance to heat and discoloration is evaluated by measuring a transmittance variation of the patterned film before and after heating the substrate in an oven at 200° C. for 60 minutes. The resistance to heat and discoloration is judged to be ‘good’ when no variation occurred and ‘poor’ when a variation is observed.

TABLE 1

| Example | | Sensitivity | UV transmittance | Resolution | Residual | Heat |
|---|---|---|---|---|---|---|
| No. | Polymer | (mJ/cm²) | (400 nm, %) | (μm) | film ratio | resistance |
| Example 1 | Synthesis | 200 | 98 | 5 | 91 | Good |
| | Example 1 | | | | | |
| Example 2 | Synthesis | 180 | 97 | 5 | 90 | Good |
| | Example 2 | | | | | |
| Example 3 | Synthesis | 190 | 98 | 5 | 91 | Good |
| | Example 3 | | | | | |
| Example 4 | Synthesis | 190 | 98 | 5 | 92 | Good |
| | Example 4 | | | | | |
| Comparative | Synthesis | 400 | 86 | 10 | 87 | Poor |
| Example 1 | Example 5 | | | | | |
| Comparative | Synthesis | 400 | 86 | 10 | 85 | Poor |
| Example 2 | Example 6 | | | | | |

The results of Table 1 demonstrate that the compositions (Examples 1-4) using the acrylic derivative substituted with a non-polar photosensitive protecting group (e.g., t-butoxycarbonyl or t-butoxy) and the photoacid generator (PAG) showed superior transmittance, sensitivity, transparency, residual film ratio and heat resistance, compared to the compositions prepared in Comparative Examples 1 and 2. Therefore, the compositions prepared in Examples 1-4 can be used to produce thick interlayer insulating films for high flatness.

As apparent from the above description, the photosensitive resin composition of the present invention exhibits high transmittance, high sensitivity, improved residual film ratio and good heat resistance. Therefore, the photosensitive resin composition of the present invention is suitable for the production of interlayer insulating films for semiconductors and liquid crystal display devices.

In addition, the epoxy group in the binder resin enables the photosensitive resin composition of the present invention to exhibit improved mechanical properties and high flatness after a curing process. Furthermore, even with a smaller amount of an acid generator than conventional dissolution inhibition type photoresist compositions, the positive type photosensitive composition of the present invention can produce an insulating film with high sensitivity and transmittance.

Many modifications and other embodiments of the invention will come to mind to one skilled in the art to which this invention pertains having the benefit of the teachings presented in the foregoing descriptions. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation, the scope of the invention being defined in the claims.

What is claimed is:

1. A photosensitive resin composition comprising a binder resin, a photoacid generator and a solvent, wherein the binder resin is an acrylic copolymer comprising structural units represented by Formulae 1, 2, 3 and 4: 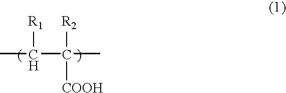
wherein R₁ and R₂ are each independently hydrogen or a methyl group; 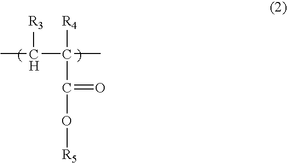
wherein R₃ and R₄ are each independently hydrogen or a methyl group, and R₅ is hydrogen, fluorine, hydroxyl, or a C₁-C₃₀ linear or cyclic alkyl, hydroxyalkyl, alkoxy, epoxy, alkoxyalkyl, ester or polycyclic group which is dissociated or not dissociated by an acid; 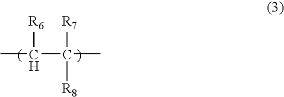
wherein R₆ and R₇ are each independently hydrogen or a methyl group, and R₈ is hydrogen, fluorine, hydroxyl, or a C₁-C₃₀ linear or cyclic alkyl, hydroxyalkyl, alkoxy, epoxy, alkoxyalkyl, ester or polycyclic group which is dissociated or not dissociated by an acid; and 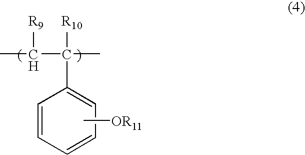
wherein R₉ and R₁₀ are each independently hydrogen or a methyl group, and R₁₁ is a methyl, ethyl, isopropyl, t-butyl, t-amyl, isobomyl, tetrahydropyranyl, naphthalenyl, isomenthyl, tricyclodecanyl, norbornyl, tetracyclododecyl, decalinyl, cyclohexyl, adamantyl, methyladamantyl, ethyladamantyl or alkoxyalkyl group.

2. The photosensitive resin composition according to claim 1, wherein the binder resin has a molecular weight (M_{w}) of about 1,000 to about 200,000.

3. The photosensitive resin composition according to claim 1, wherein the binder resin has a structure represented by Formula 5: 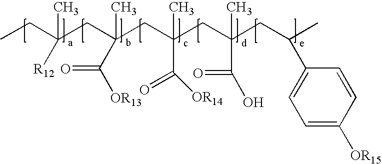
wherein R₁₂ is H, F, hydroxyl, or a C₁-C₃₀ linear or cyclic alkyl, hydroxyalkyl, alkoxy, epoxy, alkoxyalkyl, ester or polycyclic group which is dissociated or not dissociated by an acid or aryl or phenyl; R₁₃ and R₁₄ are each independently H, F, hydroxyl, or a C₁-C₃₀ linear or cyclic alkyl, hydroxyalkyl, alkoxy, epoxy, alkoxyalkyl, ester or polycyclic group which is dissociated or not dissociated by an acid; R₁₅ is a methyl, ethyl, isopropyl, t-butyl, t-amyl, isobomyl, tetrahydropyranyl, naphthalenyl, isomenthyl, tricyclodecanyl, norbomyl, tetracyclododecyl, decalinyl, cyclohexyl, adamantyl, methyladamantyl, ethyladamantyl or alkoxyalkyl group; and a, b, c, d and e represent the molar ratios of the respective structural units, are each greater than 0 and less than 1 and the sum of a, b, c, d and e is 1.

4. The photosensitive resin composition according to claim 3, wherein at least one of R₁₃ and R₁₄ is epoxy.

5. The photosensitive resin composition according to claim 3, wherein at least one of R₁₃ and R₁₄ is a polycyclic group.

6. The photosensitive resin composition according to claim 1, comprising the binder resin in an amount of about 10 to about 30 parts by weight, based on 100 parts by weight of the solvent.

7. The photosensitive resin composition according to claim 1, wherein the photoacid generator is an onium salt compound comprising a C₁-C₁₀ fluoroalkylsulfonate ion as an anion.

8. The photosensitive resin composition according to claim 1, comprising the photoacid generator in an amount of about 0.01 to about 15 parts by weight, based on 100 parts by weight of the binder resin.

9. The photosensitive resin composition according to claim 1, further comprising at least one additive selected from resins, surfactants, adhesion promoters, attachment improvers, and mixtures thereof.

10. The photosensitive resin composition according to claim 1, wherein the binder resin has a structure represented by Formula 6: 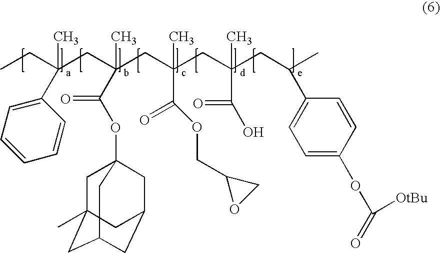
wherein each a, b, c, d and e is greater than 0 and lower than 1 and the sum of a, b, c, d and e is 1.

11. The photosensitive resin composition according to claim 1, wherein the binder resin has a structure represented by Formula 7: 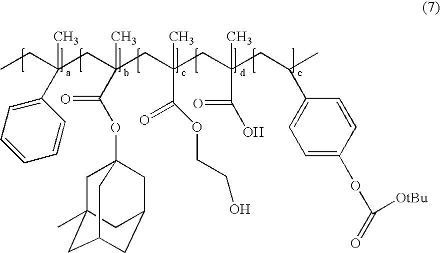
wherein each a, b, c, d and e is greater than 0 and lower than 1 and the sum of a, b, c, d and e is 1.

12. The photosensitive resin composition according to claim 1, wherein the binder resin has a structure represented by Formula 8: 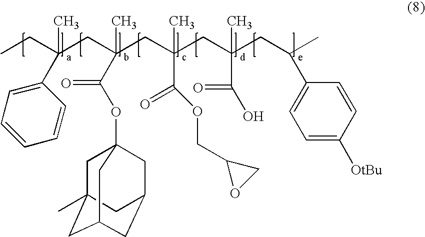
wherein each a, b, c, d and e is greater than 0 and lower than 1 and the sum of a, b, c, d and e is 1.

13. The photosensitive resin composition according to claim 1, wherein the binder resin has a structure represented by Formula 9: 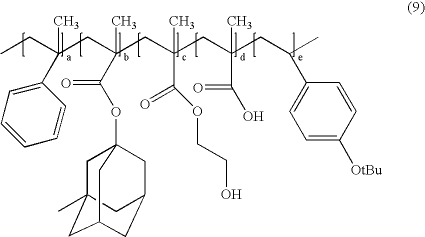
wherein each a, b, c, d and e is greater than 0 and lower than 1 and the sum of a, b, c, d and e is 1.

14. An organic insulating film produced using a photosensitive resin composition comprising a binder resin, a photoacid generator and a solvent, wherein the binder resin is an acrylic copolymer comprising structural units represented by Formulae 1, 2, 3 and 4: 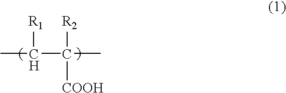
wherein R₁ and R₂ are each independently hydrogen or a methyl group; 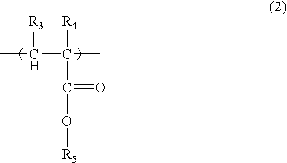
wherein R₃ and R₄ are each independently hydrogen or a methyl group, and R₅ is hydrogen, fluorine, hydroxyl, or a C₁-C₃₀ linear or cyclic alkyl, hydroxyalkyl, alkoxy, epoxy, alkoxyalkyl, ester or polycyclic group which is dissociated or not dissociated by an acid; 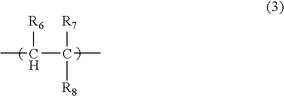
wherein R₆ and R₇ are each independently hydrogen or a methyl group, and R₈ is hydrogen, fluorine, hydroxyl, or a C₁-C₃₀ linear or cyclic alkyl, hydroxyalkyl, alkoxy, epoxy, alkoxyalkyl, ester or polycyclic group which is dissociated or not dissociated by an acid; and 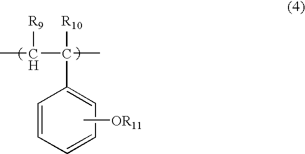
wherein R₉ and R₁₀ are each independently hydrogen or a methyl group, and R₁₁ is a methyl, ethyl, isopropyl, t-butyl, t-amyl, isobomyl, tetrahydropyranyl, naphthalenyl, isomenthyl, tricyclodecanyl, norbornyl, tetracyclododecyl, decalinyl, cyclohexyl, adamantyl, methyladamantyl, ethyladamantyl or alkoxyalkyl group.

15. The organic insulating film according to claim 14, wherein the binder resin has a structure represented by Formula 5: 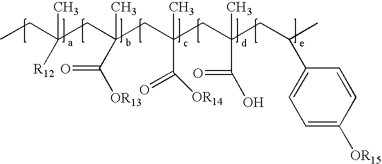
wherein R₁₂ is H, F, hydroxyl, or a C₁-C₃₀ linear or cyclic alkyl, hydroxyalkyl, alkoxy, epoxy, alkoxyalkyl, ester or polycyclic group which is dissociated or not dissociated by an acid or aryl or phenyl; R₁₃ and R₁₄ are each independently H, F, hydroxyl, or a C₁-C₃₀ linear or cyclic alkyl, hydroxyalkyl, alkoxy, epoxy, alkoxyalkyl, ester or polycyclic group which is dissociated or not dissociated by an acid; R₁₅ is a methyl, ethyl, isopropyl, t-butyl, t-amyl, isobomyl, tetrahydropyranyl, naphthalenyl, isomenthyl, tricyclodecanyl, norbornyl, tetracyclododecyl, decalinyl, cyclohexyl, adamantyl, methyladamantyl, ethyladamantyl or alkoxyalkyl group; and a, b, c, d and e represent the molar ratios of the respective structural units, are each greater than 0 and less than 1 and the sum of a, b, c, d and e is 1.

16. The organic insulating film according to claim 15, wherein at least one of R₁₃ and R₁₄ is epoxy.

17. The organic insulating film according to claim 15, wherein at least one of R₁₃ and R₁₄ is a polycyclic group.

18. A display device comprising an organic insulating film produced using a photosensitive resin composition comprising a binder resin, a photoacid generator and a solvent, wherein the binder resin is an acrylic copolymer comprising structural units represented by Formulae 1, 2, 3 and 4: 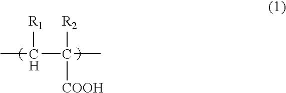
wherein R₁ and R₂ are each independently hydrogen or a methyl group; 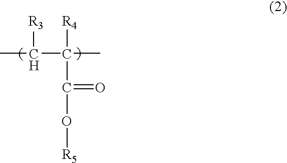
wherein R₃ and R₄ are each independently hydrogen or a methyl group, and R₅ is hydrogen, fluorine, hydroxyl, or a C₁-C₃₀ linear or cyclic alkyl, hydroxyalkyl, alkoxy, epoxy, alkoxyalkyl, ester or polycyclic group which is dissociated or not dissociated by an acid; 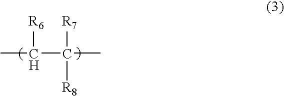
wherein R₆ and R₇ are each independently hydrogen or a methyl group, and R₈ is hydrogen, fluorine, hydroxyl, or a C₁-C₃₀ linear or cyclic alkyl, hydroxyalkyl, alkoxy, epoxy, alkoxyalkyl, ester or polycyclic group which is dissociated or not dissociated by an acid; and 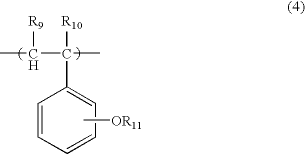
wherein R₉ and R₁₀ are each independently hydrogen or a methyl group, and R₁₁ is a methyl, ethyl, isopropyl, t-butyl, t-amyl, isobomyl, tetrahydropyranyl, naphthalenyl, isomenthyl, tricyclodecanyl, norbornyl, tetracyclododecyl, decalinyl, cyclohexyl, adamantyl, methyladamantyl, ethyladamantyl or alkoxyalkyl group.

19. The display device according to claim 18, wherein the binder resin has a structure represented by Formula 5: 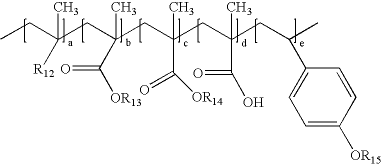
wherein R₁₂ is H, F, hydroxyl, or a C₁-C₃₀ linear or cyclic alkyl, hydroxyalkyl, alkoxy, epoxy, alkoxyalkyl, ester or polycyclic group which is dissociated or not dissociated by an acid or aryl or phenyl; R₁₃ and R₁₄ are each independently H, F, hydroxyl, or a C₁-C₃₀ linear or cyclic alkyl, hydroxyalkyl, alkoxy, epoxy, alkoxyalkyl, ester or polycyclic group which is dissociated or not dissociated by an acid; R₁₅ is a methyl, ethyl, isopropyl, t-butyl, t-amyl, isobomyl, tetrahydropyranyl, naphthalenyl, isomenthyl, tricyclodecanyl, norbornyl, tetracyclododecyl, decalinyl, cyclohexyl, adamantyl, methyladamantyl, ethyladamantyl or alkoxyalkyl group; and a, b, c, d and e represent the molar ratios of the respective structural units, are each greater than 0 and less than 1 and the sum of a, b, c, d and e is 1.
